(19) United States
(12) Patent Application Publication
(10) Pub. No.: US 2016/0211648 A1
(43) Pub. Date: Jul. 21, 2016

(54) LIGHT SOURCE DEVICE AND PROJECTOR

(71) Applicant: SEIKO EPSON CORPORATION, Tokyo (JP)

(72) Inventor: Tetsuo SHIMIZU, Matsumoto-shi (JP)

(73) Assignee: SEIKO EPSON CORPORATION, Tokyo (JP)

(21) Appl. No.: 14/990,002

(22) Filed: Jan. 7, 2016

(30) Foreign Application Priority Data
Jan. 15, 2015 (JP) 2015-005542

(51) Int. Cl. H01S 5/068; G03B 21/20

(52) U.S. Cl. CPC H01S 5/06804; G03B 21/2033; G03B 21/2053

(57) ABSTRACT

A light source device includes a laser element, a temperature sensor adapted to measure the temperature of the laser element, and a control device adapted to control a value of a current supplied to the laser element based on the measurement value obtained by the temperature sensor. Assuming that a maximum value of an output of a laser beam which the laser element can emit without being damaged is a maximum output, the control device controls the current value in accordance with the measurement value so that the output of the laser element does not exceed the maximum output.

### BACKGROUND

1. Technical Field

The present invention relates to a light source device and a projector.

2. Related Art

In the past, in the device such as a projector or a laser printer, there is used a laser diode (LD) as a light source. It is known that the laser diode is different in output value due to a variety of factors even if the laser diode is supplied with the same current (see, e.g., JP-A-62-128274).

As a representative factor varying the output value of the laser diode, there can be cited deterioration of the laser diode. The deterioration of the laser diode can be categorized into (1) the deterioration due to a temporal change in which the output value is inevitably lowered while being used, and (2) the deterioration due to a damage applied to the laser diode caused by an improper drive condition.

Among these categories, the deterioration of (2) can be suppressed by properly setting the drive condition of the laser diode. Therefore, in order to suppress the drop of the output value of the laser diode to achieve a longer operating life, it has been studied to properly set the drive condition of the laser diode.

### SUMMARY

An advantage of some aspects of the invention is to provide a light source device having a laser diode inhibited from being damaged, and having a long operating life. Another advantage of some aspects of the invention is to provide a projector having such a light source device, and having a long operating life.

An aspect of the invention provides a light source device including a laser element, a temperature sensor adapted to one of directly and indirectly measure the temperature of the laser element, and a control device adapted to control a value of a current supplied to the laser element based on the measurement value obtained by the temperature sensor. Assuming that a maximum value of an output of a laser beam which the laser element can emit without being damaged is a maximum output, the control device controls the current value in accordance with the measurement value so that the output of the laser element is one of equal to and lower than the maximum output.

According to this configuration, since there is no chance of supplying an excessive current to the laser element, the damage to the laser element is suppressed. Thus, the light source device having a long operating life can be provided.

The aspect of the invention may adopt a configuration in which the control device controls the current value to a first current value, with which the output of the laser element is one of equal to and lower than the maximum output, at startup of the laser element, and the control device controls the current value to a second current value higher than the first current value in a case in which the temperature of the laser element is in a steady state.

According to this configuration, since there is no chance of supplying an excessive current to the laser element at the lower temperature than in the steady state at the startup of the laser element, the damage to the laser element is suppressed.

The aspect of the invention may adopt a configuration in which the control device increases the current value from the first current value to the second current value in a stepwise manner.

According to this configuration, it is possible to make the current value reach the second current value in a shorter period of time.

The aspect of the invention may adopt a configuration in which the control device continuously increases the current value from the first current value to the second current value.

According to this configuration, it is possible to make the current value reach the second current value in a shorter period of time. Further, since ringing in which the current value vibrates does not occur, overshoot of the current value does not occur. Therefore, there is no chance of supplying an excessive current. Therefore, a catastrophic optical damage of the laser element can effectively be suppressed.

The aspect of the invention may adopt a configuration in which the control device controls the current value so that a time period from the startup of the laser element to when the current value is set to the second current value becomes shorter.

According to this configuration, it is possible to promptly emit the laser beam with a desired output value from the light source device.

The aspect of the invention may adopt a configuration in which the control device controls the current value based on a correspondence relationship between the temperature of the laser element and the output value of the laser element so that the output value approaches the maximum output.

According to this configuration, it is possible to emit the laser beam with the maximum output or an output approximate to the maximum output at the startup of the light source device.

The aspect of the invention may adopt a configuration in which the control device controls the current value in accordance with cumulative operating time of the laser element.

According to this configuration, even if a deterioration due to the temporal change advances in the laser element, the current value not causing the catastrophic optical damage can be supplied, and thus, the damage of the laser element can be suppressed. Further, since appropriate control can be achieved by measuring the cumulative operating time, the control is easy.

The aspect of the invention may adopt a configuration in which the control device controls the current value in accordance with a variation in actual measurement value of the output value of the laser element with respect to the same current value.

According to this configuration, even if a deterioration due to the temporal change advances in the laser element, the current value not causing the catastrophic optical damage can be supplied, and thus, the damage of the laser element can be suppressed. Further, since the control is performed in accordance with the actual measurement value of the output value, reliable control becomes possible.

Another aspect of the invention provides a projector including the light source device described above, a light modulation device adapted to modulate light emitted from the light source device, and a projection optical system adapted to project the light modulated by the light modulation device.

According to this configuration, since the projector includes the light source device according to the invention described above, the light intensity is difficult to be lowered, and an operating life is prolonged.

### BRIEF DESCRIPTION OF THE DRAWINGS

The invention will be described with reference to the accompanying drawings, wherein like numbers reference like elements.

FIG. 1 is a schematic diagram of a light source device according to an embodiment of the invention.

FIG. 2 is a graph showing a correspondence relationship between the temperature of a laser element and an output value of the laser element.

FIG. 3 is a graph showing a correspondence relationship between lighting time of the laser element and the temperature of the laser element.

FIG. 4 is a graph showing a correspondence relationship between the lighting time of the laser element and a current value controlled by a control device.

FIG. 5 is a graph showing a correspondence relationship between the lighting time of the laser element and the current value controlled by the control device.

FIG. 6 is a graph showing a correspondence relationship between the lighting time of the laser element and the current value controlled by the control device.

FIG. 7 is a graph showing a correspondence relationship between the lighting time of the laser element and the current value controlled by the control device.

FIG. 8 is a top view showing an optical system of a projector according to the embodiment.

FIGS. 9A and 9B are explanatory diagrams of a rotary phosphor plate in the present embodiment.

### DESCRIPTION OF EXEMPLARY EMBODIMENTS

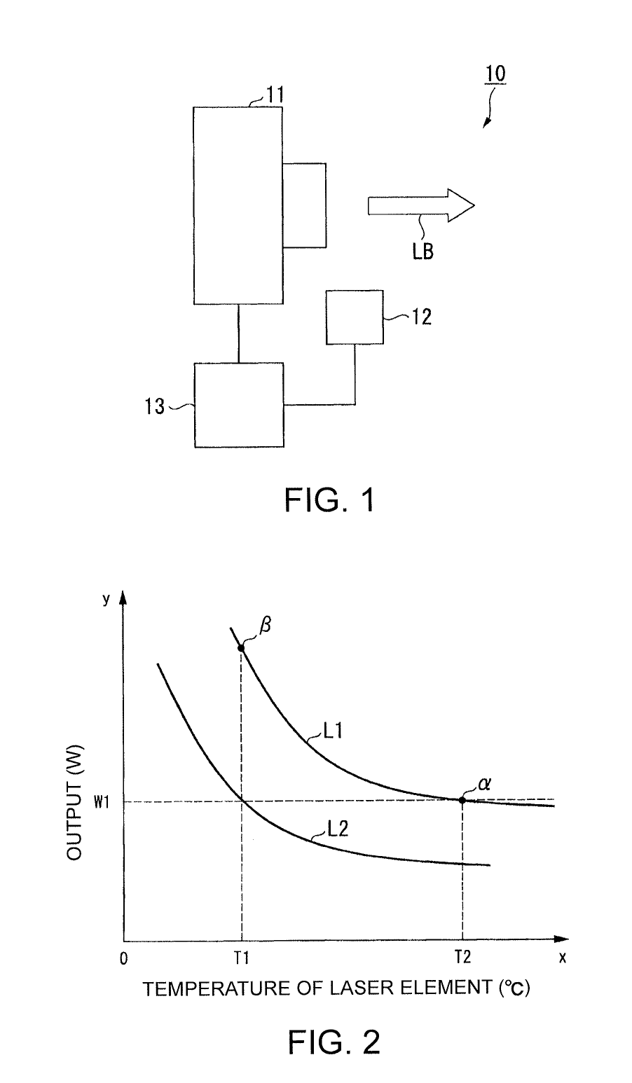

Hereinafter, a light source device according to an embodiment of the invention will be explained with reference to FIGS. 1 through 7. It should be noted that in all of the drawings described below, the sizes and the ratios between the sizes of the constituents are arbitrarily made different from each other in order to make the drawings eye-friendly.

FIG. 1 is a schematic diagram of a light source device according to the present embodiment of the invention. As shown in the diagram, the light source 10 device according to the present embodiment includes a laser element 11, a temperature sensor 12, and a control device 13.

The laser element 11 is a solid-state light source for emitting a laser beam LB. As the laser element 11, a semiconductor laser element (a laser diode), for example, can be used.

As the laser element 11, there can be used an element for emitting a variety of types of light in accordance with the design of the light source device 10. In the case of, for example, irradiating a phosphor material with the laser beam LB emitted from the light source device 10 to make the phosphor material generate the phosphor, namely the case of using the laser beam LB emitted therefrom as the excitation light, an element for emitting a blue laser beam having a light intensity peak at about 445 nm can be used as the laser element 11.

The temperature sensor 12 is a sensor for directly or indirectly measuring the temperature of the laser element 11. At the startup of the laser element 11, the temperature of the laser element 11 is roughly equal to the temperature of the environment in which the laser element 11 is disposed. Therefore, by measuring the environmental temperature of the laser element 11, the temperature of the laser element 11 can indirectly be measured.

The temperature sensor 12 measures the temperature of the laser element 11 at the time of startup. Further, it is also possible for the temperature sensor 12 to continue to measure the temperature of the laser element 11 continuously during lighting of the laser element 11, or to measure the temperature intermittently.

As the temperature sensor 12, a known sensor can be used providing the temperature of the laser element 11 can directly or indirectly be measured.

The control device 13 obtains the measurement value thus obtained by the temperature sensor 12, and controls a value of a current input to the laser element 11 based on the measurement value thus obtained.

In the semiconductor laser element, in the case of increasing the amount of the current input, an exit end surface of the laser beam in the laser element suffers a damage called a catastrophic optical damage (COD) whereby the output decreases in some cases. The catastrophic optical damage is caused in the following mechanism.

Firstly, when the semiconductor laser element is supplied with an excessive current, the electrons and the holes are recombined with each other via the surface level existing on the exit end surface to generate a current not accompanied with light emission. Therefore, in the vicinity of the exit end surface, the density of the electrons and the holes becomes higher compared to the inside of the laser element, and it becomes easy to absorb the laser beam.

The exit end surface generates heat due to absorption of the laser beam. Then, in the vicinity of the exit end surface, the band-gap energy drops to further make it easy to absorb the laser beam.

In such a manner as described above, due to the temperature of the exit end surface rising to a melting point, the exit end surface suffers the catastrophic optical damage.

In contrast, the light source device 10 according to the present embodiment is arranged to suppress the catastrophic optical damage as described below to achieve a longer operating life.

FIG. 2 is a graph showing a correspondence relationship between the temperature of the laser element 11 and an output value of the laser element 11 when supplying a constant current. In the graph, the horizontal axis represents the temperature (unit: ° C.), and the vertical axis represents the output value (unit: W). As shown in the drawing, in the laser element 11, when the temperature is relatively low, the output value is high. The reason is that when the temperature of the laser element 11 is low, the internal resistance drops, and it becomes easy for the current to flow.

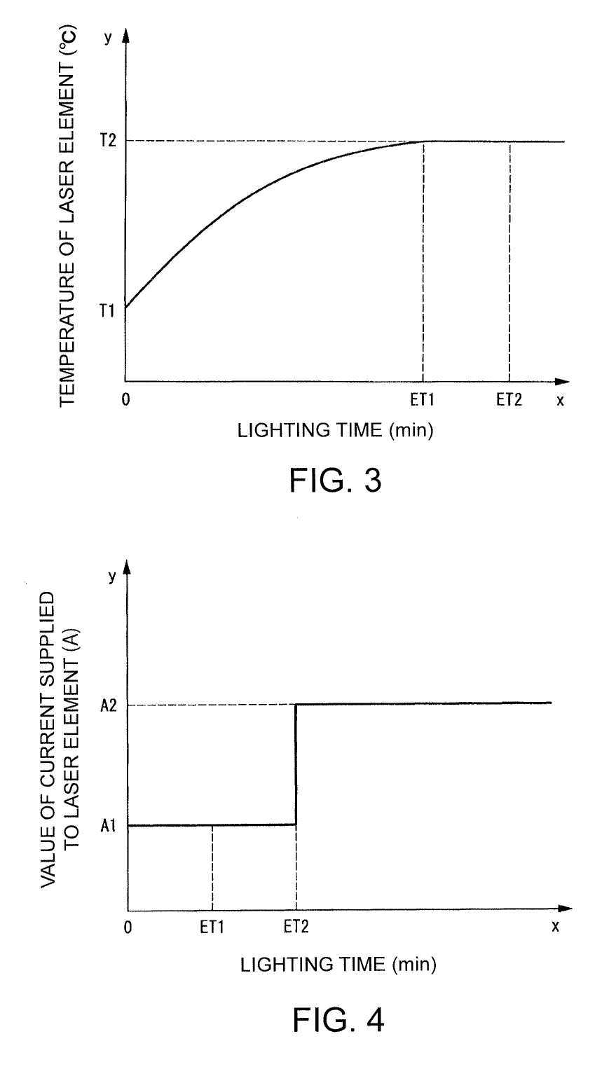

FIG. 3 is a graph showing a correspondence relationship between lighting time of the laser element 11 and the temperature of the laser element 11 in the light source device 10. In the graph, the horizontal axis represents the time (unit: minute), and the vertical axis represents the temperature (unit: ° C.). Since the laser element 11 generates heat, as shown in FIG. 3, the temperature of the laser element 11 rises with time. However, after the time ET2 has elapsed, the temperature of the laser element 11 converges on the temperature corresponding to the balance between the heat generation by driving and cooling by heat radiation, and then becomes roughly constant. It should be noted that the lighting time means the elapsed time from the startup of the laser element 11.

The temperature of the laser element 11 in the steady state of the temperature is denoted as T2. The temperature T2 is higher than the environmental temperature T1 of the laser element 11, and depends on a disturbance factor such as the environmental temperature or a cooling efficiency of the projector.

Here, the maximum value of the output of the laser beam, which the laser element 11 can emit without being damaged at the temperature T2, is defined as a maximum output W1. Further, a current necessary to obtain the maximum output W1 at the temperature T2 is defined as a current A2. The current A2 corresponds to a second current value in the appended claims.

In FIG. 2, the graph L1 shows the correspondence relationship between the temperature of the laser element 11 and the output value of the laser element 11 in the case in which the laser element 11 is supplied with the current A2. In the graph L1, the output value obtained at the temperature T2 is the maximum output W1. In the graph L1, the point corresponding to the temperature T2 and the maximum output W1 is denoted with the symbol α.

Further, in FIG. 2, the graph L2 shows the correspondence relationship between the temperature of the laser element 11 and the output value of the laser element 11 in the case of supplying a current A1 smaller than the current A2. The current A1 corresponds to a first current value in the appended claims.

At the startup of the laser element 11, the temperature of the laser element 11 is roughly equal to the environmental temperature T1. The environmental temperature T1 is lower than the temperature T2. Therefore, if the current A2 is supplied at the startup in order to make the laser element 11 emit the laser beam of the maximum output W1, the output value exceeds the maximum output W1 as indicated by the symbol β, and the laser element 11 suffers the catastrophic optical damage.

Therefore, in the light source device 10 according to the present embodiment, the control device 13 controls the value of the current to be supplied to the laser element 11 based on the measurement value obtained by the temperature sensor 12. Hereinafter, the explanation will be presented with reference to FIGS. 3 and 4.

The control device 13 stores the relationship between the temperature and the lighting time shown in FIG. 3. It is also possible for the control device 13 to store the graph shown in FIG. 3 as numerical formulas, or to store the temperature values at predetermined points of the lighting time in a table form. Further, it is preferable to store the relationship between the temperature and the lighting time with respect to a plurality of current values. Further, it is preferable to store the relationship between the temperature and the lighting time with respect to a plurality of values of the environmental temperature T1.

FIG. 4 is a graph showing a correspondence relationship between lighting time of the laser element 11 and the value of the current to be supplied by the control device 13 to the laser element 11 in the light source device 10. In the graph, the horizontal axis represents the time (unit: minute), and the vertical axis represents the current value (unit: A).

Before the startup, the temperature sensor 12 measures the environmental temperature T1 to directly or indirectly measure the temperature of the laser element 11. Since the value (the environmental temperature T1) measured by the temperature sensor 12 is lower than the temperature T2, the control device 13 supplies the current A1 smaller than the current A2 at the startup of the laser element 11 as shown in FIG. 4.

As shown in the graph L2 of FIG. 2, the current A1 is a value with which the output of the laser element 11 does not exceed the maximum output W1 in the case in which the temperature of the laser element 11 is T1. It is preferable to set the current A1 as high as possible within a range in which the maximum output W1 is not exceeded. According to this configuration, a sufficiently high output can be obtained while suppressing the catastrophic optical damage.

The control device 13 can approximate the time (time ET1) necessary for the temperature of the laser element 11 to reach the temperature T2 based on the stored correspondence relationship between the lighting time of the laser element 11 and the temperature of the laser element 11. It is conceivable that in reality, the temperature of the laser element 11 is shifted from the correspondence relationship shown in FIG. 3 due to the disturbance factor such as the environmental temperature or the cooling efficiency of the projector. Therefore, the control device 13 determines time ET2 longer than the time ET1. The time ET2 is the time at which the temperature of the laser element 11 is assumed to reach the temperature T2 taking the disturbance factor into consideration.

As shown in FIG. 4, the control device 13 sets the current value to A1 until the time ET2 elapses. When the time ET2 has elapsed, the control device 13 raises the current value from the current A1 so as to approach the current A2 but not to exceed the current A2. In the example shown in FIG. 4, the control device 13 switches the current value from the current A1 to the current A2 in a stepwise manner (discontinuously at the time ET2) when the time ET2 has elapsed.

Since the current value is set to a sufficiently low value in a period from when the laser element 11 is started up to when the temperature of the laser element 11 reaches T2 as described above, the catastrophic optical damage does not occur. Further, even after the temperature of the laser element 11 has reached T2, the current value is set to A2, and therefore the catastrophic optical damage does not occur.

According to such a light source device 10 as described above, it is possible to provide a light source device, in which the damage of the laser diode is inhibited, and which has a long operating life.

It should be noted that the following modified examples of the light source device 10 can be cited in terms of a method of controlling the current value by the control device 13.

### Modified Example 1

In the case of, for example, making the temperature sensor 12 have contact with the laser element 11, the temperature of the laser element 11 can accurately be measured. In this case, the temperature sensor 12 can measure the current temperature of the laser element 11, and the control device 13 can switch the current value from the current A1 to the current A2 in response to the measurement value by the temperature sensor 12 showing the temperature T2. By controlling the current value as described above, it is possible to shorten the period during which the laser element 11 is outputting a relatively weak laser beam.

### Modified Example 2

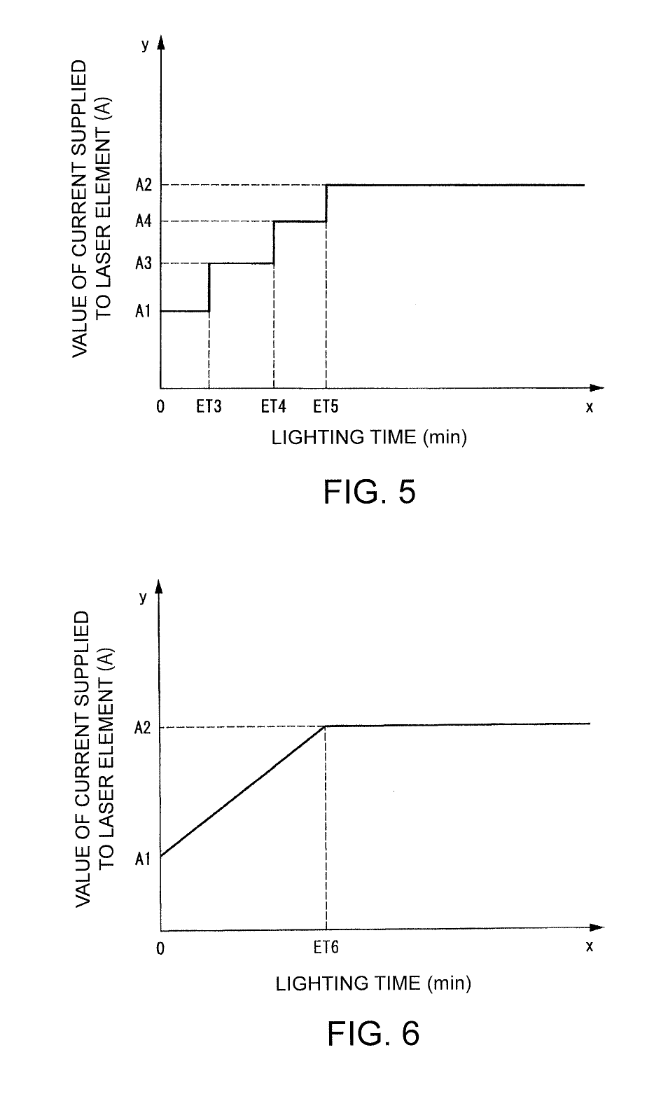

As shown in FIG. 5, it is also possible to increase the current value from the current A1 to the current A2 in two or more times in a stepwise manner.

For example, the control device 13 sets the current value to the current A1 from the startup to time ET3, switches the current value from the current A1 to a current A3 at the time ET3 in a stepwise manner, switches the current value from the current A3 to a current A4 at time ET4 in a stepwise manner, and switches the current value from the current A4 to the current A2 at time ET5 in a stepwise manner. It should be noted that the current A3 and the current A4 are both values not causing the catastrophic optical damage in the laser element 11.

If the value of the current supplied to the laser element 11 increases, an amount of heat generation in the laser element 11 also increases, and therefore, the time necessary for the temperature of the laser element 11 to reach the temperature T2 becomes shorter. Therefore, it is possible to make the current value reach the current A2 in a shorter period of time. In other words, it is possible to set the time ET5 to a value shorter than the time ET2.

Further, since the current value becomes higher after the time ET3 has elapsed, the laser element 11 can output an intense laser beam compared to the case of keeping the current value to the current A1 until the time ET2 elapses.

### Modified Example 3

As shown in FIG. 6, it is also possible for the control device 13 to continuously increase the current value from the current A1 to the current A2. It should be noted that it is necessary to increase the current value in a range in which the catastrophic optical damage is not caused in the laser element 11.

In the case in which the current value is changed in a stepwise manner as shown in FIGS. 4 and 5, there is a possibility that there occurs “ringing,” in which the current value vibrates, to make the current value instantaneously overshoot. In the case in which the overshot current value is higher than a predetermined current value, an excessive current is supplied to the laser element 11 although instantaneously, and there is a possibility of causing the catastrophic optical damage.

In contrast, in the case of continuously increasing the current to be supplied to the laser element 11 as shown in FIG. 6, the ringing does not occur, and therefore, the current value does not overshoot, and thus, there is no chance of supplying an excessive current. Therefore, the catastrophic optical damage of the laser element 11 can effectively be suppressed.

In the case of continuously increasing the current value, the time ET6 necessary for the current value to reach the current A2 can be set to be shorter than the time ET5. Further, until the current value reaches the current A2, the laser element 11 can emit a more intense laser beam than in the case of the embodiment, Modified Examples 1, 2.

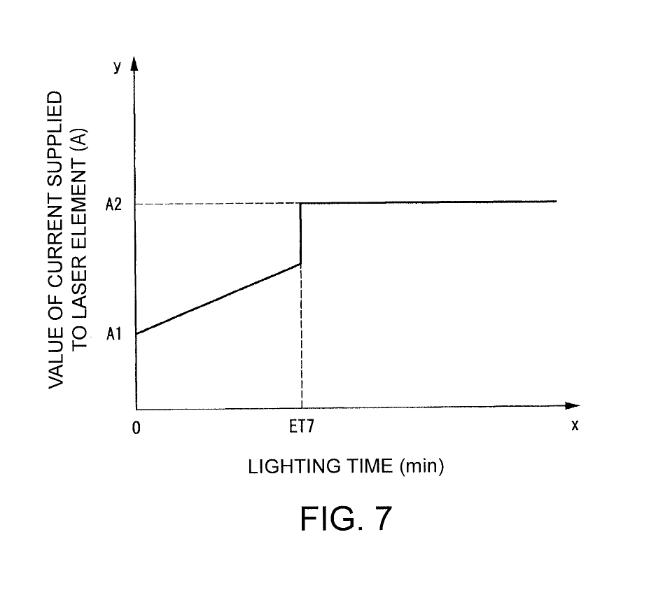

Further, as shown in FIG. 7, it is also possible to use both of the control for continuously changing the current value and the control for changing the current value in a stepwise manner. For example, it is also possible to continuously increase the value of the current to be supplied until the temperature of the laser element 11 reaches the temperature T2, and then change the value of the current to be supplied to the current A2 at a time after the temperature of the laser element 11 has reached the temperature T2.

### Modified Example 4

In the Modified Example 2 or Modified Example 3, it is preferable to control the value of the current to be supplied so that the output value of the laser element 11 is equal to or lower than the maximum output W1 but as close as possible to the maximum output W1 during the period of increasing the current value to be supplied from the current A1 to the current A2. In this case, the value of the current supplied at each of the time points can be determined in accordance with the temperature of the laser element 11 at the time point. The amount of the current necessary to make the laser element 11 output the laser beam of the maximum output W1 at that temperature can be obtained from the correspondence relationship shown in FIG. 2.

The temperature of the laser element 11 at each of the time points can be estimated from the correspondence relationship shown in FIG. 3, or can be obtained by measuring the temperature using the temperature sensor 12 at each of the time points.

By performing the control as described above, it is possible to emit the laser beam with sufficiently high output within a range in which the catastrophic optical damage is not applied from the startup of the light source device 10.

### Modified Example 5

The laser element 11 is dropped in the output due to the temporal change even if the laser element does not suffer the catastrophic optical damage. Therefore, it is preferable for the control device 13 to control the value of the current A1 supplied when starting up the laser element 11 in accordance with the degree of deterioration due to the temporal change.

Here, the “degree of deterioration” can be taken as a ratio between the output value (initial output value) obtained when supplying a new laser element with a predetermined current and the output value obtained when supplying the laser element deteriorated due to the temporal change with the predetermined current described above at certain temperature. If the control device 13 stores the initial output value of the laser element in advance as information, the degree of deterioration can be obtained based on the comparison with the output value of the current (after temporally changed) laser element.

The degree of deterioration can also be estimated from the cumulative operating time of the laser element based on the correspondence relationship between the cumulative operating time and the output value of the laser element. In the case of obtaining the degree of deterioration in such a manner as described above, since the appropriate control can be performed by measuring the cumulative operating time, the control becomes easy.

Further, it is possible to arrange that there is provided a sensor for detecting the intensity of the laser beam emitted from the laser element to measure the actual output value. In the case of obtaining the degree of deterioration in such a manner as described above, since the control corresponding to the actual measurement value of the output value can be performed, it becomes possible to perform reliable control.

By performing the control in accordance with the degree of deterioration as described above, even in the case in which the deterioration due to the temporal change advances in the laser element 11, the current value not causing the catastrophic optical damage can preferably be supplied, and thus, the damage of the laser element 11 can be suppressed.

According to such a light source device 10 as described above, it is also possible to provide a light source device, in which the damage of the laser diode is inhibited, and which has a long operating life.

### Modified Example 6

After the temperature of the laser element 11 becomes the steady state, the temperature varies due to some factor in some cases. In the case in which the temperature is lowered, if a current such as the current A2 continues to be supplied to the laser element 11, there is a possibility that the catastrophic optical damage occurs. Therefore, in the case in which the temperature of the laser element 11 is measured at predetermined time intervals using the temperature sensor 12, and the measurement value becomes lower than the temperature T2, it is preferable for the control device 13 to decrease the current value.

### Projector

Then, a configuration of the projector 1000 according to the present embodiment will be explained.

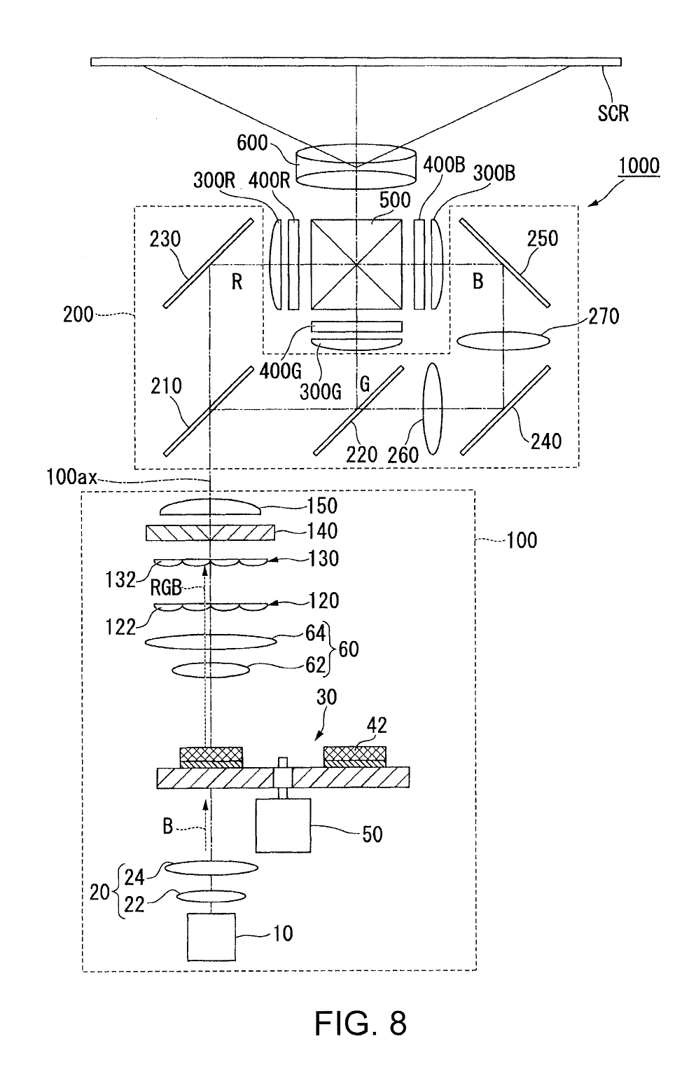

FIG. 8 is an explanatory diagram showing an optical system of the projector 1000 according to the embodiment. It should be noted that in FIG. 8, in order to make the explanation easy, the constituents of the rotary phosphor plate 30 are illustrated with the thickness thereof exaggerated. The same applies to the drawings mentioned later.

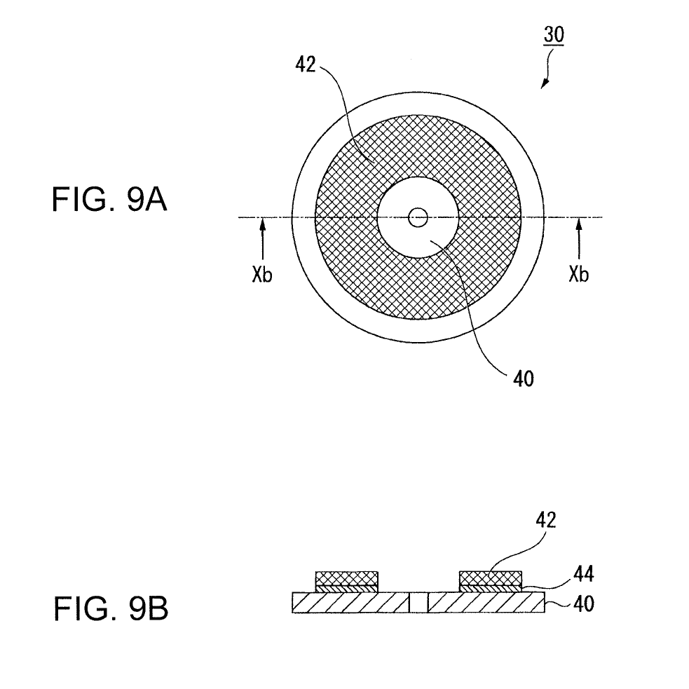

FIGS. 9A and 9B are diagrams for explaining the rotary phosphor plate 30 in the present embodiment. FIG. 9A is a front view of the rotary phosphor plate 30, and FIG. 9B is an Xb-Xb cross-sectional view of FIG. 9A.

As shown in FIG. 8, the projector 1000 according to the present embodiment is provided with the illumination device 100, a color separation light guide optical system 200, a liquid crystal light modulation device (a light modulation device) 400R, a liquid crystal light modulation device (alight modulation device) 400G, a liquid crystal light modulation device (a light modulation device) 400B, a cross dichroic prism 500, and a projection optical system 600.

The illumination device 100 is provided with the light source device 10, a light collection optical system 20, the rotary phosphor plate 30, an electric motor 50, a collimating optical system 60, a first lens array 120, a second lens array 130, a polarization conversion element 140, and an overlapping lens 150. As the light source device 10, there is used the light source device according to the invention described above.

The light source device 10 has the laser element 11 for emitting blue light formed of the laser beam as excitation light. The peak wavelength of the blue light is, for example, 445 nm.

It should be noted that the light source device can include a single laser element 11, or can also include a plurality of laser elements 11. Further, it is also possible to adopt a light source device for emitting the blue light having a wavelength (e.g., 460 nm) other than 445 nm.

The light collection optical system 20 is provided with a first lens 22 and a second lens 24. The light collection optical system 20 is disposed in the light path from the light source device 10 to the rotary phosphor plate 30, and collectively makes the blue light enter a phosphor layer 42 (described later) in a roughly collected state. The first lens 22 and the second lens 24 are each formed of a convex lens.

The rotary phosphor plate 30 is a so-called transmissive rotary phosphor plate, and is obtained by continuously forming a single phosphor layer 42 on a part of a circular disk 40, which can be rotated by the electric motor 50, along the circumferential direction of the circular disk 40 as shown in FIGS. 8, 9A, and 9B. The blue light enters the phosphor layer 42. The rotary phosphor plate 30 is configured so as to emit the red light and the green light toward the side opposite to the side to which the blue light is input.

The circular disk 40 is made of a material transmitting the blue light. It is arranged that the blue light from the light source device 10 enters the phosphor layer 42 from the circular disk 40 side.

The phosphor layer 42 is formed on the circular disk 40 via a dichroic film 44 transmitting the blue light and reflecting the red light and the green light. The dichroic film 44 is formed of, for example, a dielectric multilayer film.

The phosphor layer 42 includes, for example, (Y, Gd)₃(Al, Ga)₅O₁₂:Ce as a YAG phosphor material. The phosphor layer 42 converts a part of the blue light from the light source device 10 into the light including the red light and the green light, and at the same time transmits the remaining part of the blue light without performing the conversion.

As shown in FIG. 8, the collimating optical system 60 is provided with a first lens 62 for preventing the light from the rotary phosphor plate 30 from spreading, and a second lens 64 for roughly collimating the light from the first lens 62, and collectively has a function of roughly collimating the light from the rotary phosphor plate 30. The first lens 62 and the second lens 64 are each formed of a convex lens.

The first lens array 120 has a plurality of first small lenses 122 for dividing the light from the collimating optical system 60 into a plurality of partial light beams. The first lens array 120 has a configuration of arranging the plurality of first small lenses 122 in a matrix in a plane perpendicular to the illumination light axis 100ax. Although the explanation with a graphical description will be omitted, an outer shape of the first small lens 122 is roughly similar to an outer shape of each of the image forming areas of the respective liquid crystal light modulation devices 400R, 400G, and 400B.

The second lens array 130 has a plurality of second small lenses 132 corresponding to the plurality of first small lenses 122 of the first lens array 120. The second lens array 130 has a function of imaging the image of each of the first small lenses 122 of the first lens array 120 in the vicinity of the image forming areas of the liquid crystal light modulation device 400R in cooperation with the overlapping lens 150. Similarly, the second lens array 130 images the image of each of the first small lenses 122 of the first lens array 120 in the vicinity of the image forming area of the liquid crystal light modulation device 400G, and images the image in the vicinity of the image forming area of the liquid crystal light modulation device 400B together with the overlapping lens 150.

The polarization conversion element 140 is a polarization conversion element for converting each of the partial beams split into by the first lens array 120 into a substantially unique linearly polarized light beam having a uniform polarization direction, and emitting the resulted partial light beams.

The overlapping lens 150 is an optical element for collecting each of the partial light beams from the polarization conversion element 140 to overlap the partial light beams in the vicinity of each of the image forming areas of the liquid crystal light modulation devices 400R, 400G, and 400B. The first lens array 120, the second lens array 130, and the overlapping lens 150 constitute an integrator optical system for homogenizing the in-plane light intensity distribution of the light from the rotary phosphor plate 30.

The color separation light guide optical system 200 is provided with dichroic mirrors 210, 220, reflecting mirrors 230, 240, and 250, and relay lenses 260, 270. The color separation light guide optical system 200 separates the light from the illumination device 100 into the red light, the green light, and the bluelight. Further, the color separation light guide optical system 200 guides the red light to the liquid crystal light modulation device 400R as the irradiation target of the red light. Similarly, the color separation light guide optical system 200 guides the green light to the liquid crystal light modulation device 400G as the irradiation target of the green light, and guides the blue light to the liquid crystal light modulation device 400G as the irradiation target of the blue light.

The collecting lens 300R is disposed between the color separation light guide optical system 200 and the liquid crystal light modulation device 400R. Similarly, the collecting lens 300G is disposed between the color separation optical system 200 and the liquid crystal light modulation device 400G, and the collecting lens 300B is disposed between the color separation light guide optical system 200 and the liquid crystal light modulation device 400B.

The dichroic mirror 210 is a dichroic mirror for transmitting the red light component and reflecting the green light component and the blue light component.

The dichroic mirror 220 is a dichroic mirror for reflecting the green light component and transmitting the blue light component.

The liquid crystal light modulation devices 400R, 400G, and 400B are for modulating the respective colored light beams having entered the liquid crystal light modulation devices in accordance with the image information to thereby form a color image, and are the illumination target of the illumination device 100.

It should be noted that although not shown in the drawings, an incident side polarization plate is disposed between the collecting lens 300R and the liquid crystal light modulation device 400R. Similarly, an incident side polarization plate is disposed between the collecting lens 300G and the liquid crystal light modulation device 400G, and an incident side polarization plate is disposed between the collecting lens 300B and the liquid crystal light modulation device 400B.

Further, an exit side polarization plate is disposed between the liquid crystal light modulation device 400R and the cross dichroic prism 500. Similarly, an exit side polarization plate is disposed between the liquid crystal light modulation device 400G and the cross dichroic prism 500, and an exit side polarization plate is disposed between the liquid crystal light modulation device 400B and the cross dichroic prism 500.

The cross dichroic prism 500 is an optical element for combining the optical images modulated for respective colored light beams emitted from the respective exit side polarization plates to thereby form a color image.

The color image emitted from the cross dichroic prism 500 is projected in an enlarged manner by the projection optical system 600 to form an image on the screen SCR.

The projector 1000 according to the present embodiment has the configuration described above.

According to the projector 1000 having the configuration described above, since the light source device 10 according to the invention described above is provided, the light intensity is difficult to be lowered, and an operating life is prolonged.

Although the explanation is hereinabove presented regarding the preferable embodiment of the invention with reference to the accompanying drawings, it is obvious that the invention is not limited to the embodiment described above. The various shapes and combinations of the constituents presented in the embodiment described above are illustrative only, and can variously be modified within the spirit or the scope of the invention in accordance with design needs and so on.

For example, a digital micromirror device can also be used as the light modulation device. Further, the light source device according to the invention can also be applied to lighting equipment, a headlight of a vehicle, and so on.

The entire disclosure of Japanese Patent Application No. 2015-005542, filed on Jan. 15, 2015 is expressly incorporated by reference herein.

What is claimed is:

1. A light source device comprising:
a laser element;
a temperature sensor adapted to one of directly and indirectly measure the temperature of the laser element; and
a control device adapted to control a value of a current supplied to the laser element based on the measurement value obtained by the temperature sensor,
wherein assuming that a maximum value of an output of a laser beam which the laser element can emit without being damaged is a maximum output, the control device controls the current value in accordance with the measurement value so that the output of the laser element is one of equal to and lower than the maximum output.

2. The light source device according to claim 1, wherein
the control device controls the current value to a first current value, with which the output of the laser element is one of equal to and lower than the maximum output, at startup of the laser element, and
the control device controls the current value to a second current value higher than the first current value in a case in which the temperature of the laser element is in a steady state.

3. The light source device according to claim 2, wherein
the control device increases the current value from the first current value to the second current value in a stepwise manner.

4. The light source device according to claim 2, wherein
the control device continuously increases the current value from the first current value to the second current value.

5. The light source device according to claim 3, wherein
the control device controls the current value so that a time period from the startup of the laser element to when the current value is set to the second current value becomes shorter.

6. The light source device according to claim 1, wherein
the control device controls the current value based on a correspondence relationship between the temperature of the laser element and the output value of the laser element so that the output value approaches the maximum output.

7. The light source device according to claim 1, wherein
the control device controls the current value in accordance with cumulative operating time of the laser element.

8. The light source device according to claim 1, wherein
the control device controls the current value in accordance with a variation in actual measurement value of the output value of the laser element with respect to the same current value.

9. A projector comprising:
the light source device according to claim 1;
a light modulation device adapted to modulate light emitted from the light source device; and
a projection optical system adapted to project the light modulated by the light modulation device.

10. A projector comprising:
the light source device according to claim 2;
a light modulation device adapted to modulate light emitted from the light source device; and
a projection optical system adapted to project the light modulated by the light modulation device.

11. A projector comprising:
the light source device according to claim 3;
a light modulation device adapted to modulate light emitted from the light source device; and
a projection optical system adapted to project the light modulated by the light modulation device.

12. A projector comprising:
the light source device according to claim 4;
a light modulation device adapted to modulate light emitted from the light source device; and
a projection optical system adapted to project the light modulated by the light modulation device.

13. A projector comprising:
the light source device according to claim 5;
a light modulation device adapted to modulate light emitted from the light source device; and
a projection optical system adapted to project the light modulated by the light modulation device.

14. A projector comprising:
the light source device according to claim 6;
a light modulation device adapted to modulate light emitted from the light source device; and
a projection optical system adapted to project the light modulated by the light modulation device.

15. A projector comprising:
the light source device according to claim 7;
a light modulation device adapted to modulate light emitted from the light source device; and
a projection optical system adapted to project the light modulated by the light modulation device.

16. A projector comprising:
the light source device according to claim 8;
a light modulation device adapted to modulate light emitted from the light source device; and
a projection optical system adapted to project the light modulated by the light modulation device.
